(19) United States
(12) Patent Application Publication
(10) Pub. No.: US 2025/0366292 A1
(43) Pub. Date: Nov. 27, 2025

(54) DISPLAY PANEL

(71) Applicant: LG Display Co., Ltd., Seoul (KR)

(72) Inventors: Dan Lyoul MA, Paju-si (KR); Hyoung Sun PARK, Paju-si (KR); Hyun Seok NA, Paju-si (KR)

(73) Assignee: LG Display Co., Ltd., Seoul (KR)

(21) Appl. No.: 19/217,480

(22) Filed: May 23, 2025

(30) Foreign Application Priority Data
May 24, 2024 (KR) 10-2024-0067853

(51) Int. Cl. H10H 29/41; H10H 29/49

(52) U.S. Cl. CPC H10H 29/41; H10H 29/49

(57) ABSTRACT

Disclosed herein is a display panel including a pixel driver in a display area and an insulating layer disposed under and covered by a planarization layer. The insulating layer includes an upper insulating layer having one or more openings that expose a plurality of pads of the pixel driver, allowing electrical connection to external lines. By positioning the insulating layer between the planarization layer and the pixel driver, the structure reduces the likelihood of pore formation caused by adhesion failure or thermal stress, thereby enhancing reliability and manufacturing yield.

### CROSS-REFERENCE TO RELATED APPLICATION

This application claims priority to and the benefit of Korean Patent Application No. 10-2024-0067853, filed on May 24, 2024, the disclosure of which is incorporated herein by reference in its entirety.

### BACKGROUND

### Technical Field

The present disclosure relates to a display panel, and in particular to the display panel including a pixel driver.

### Description of Related Art

Electroluminescent displays (hereinafter referred to as “display devices”) may be classified into organic light-emitting displays in which organic light-emitting diodes (OLEDs) are disposed in pixels, and inorganic light-emitting displays in which inorganic light-emitting diodes (hereinafter referred to as “LEDs”) are disposed in pixels.

Since electroluminescent displays display images using self-light emitting elements, the electroluminescent displays do not require separate light sources, for example, backlight units, and thus may be implemented in thin and various forms. Electroluminescent displays not only have low power consumption and excellent response speed, brightness, and viewing angle, but also have excellent contrast ratio and color reproducibility because electroluminescent displays may express black gradations such as complete black.

### BRIEF SUMMARY

The present disclosure addresses a technical issue observed in conventional display devices, in which oxidation may occur between an organic light-emitting layer and the electrodes due to infiltration of oxygen and moisture.

For instance, when a pixel driver for driving pixels including micro light-emitting diodes (LEDs) is disposed under and buried by a planarization layer (in other words, disposed under and embedded in a planarization layer) within a display area, pores or cracks may be generated by a difference in thermal expansion coefficients of the planarization layer and the pixel driver during a subsequent process due to low adhesion between the planarization layer and the pixel driver. To address this, various embodiments are provided that include structures designed to prevent such infiltration and promote stable performance of organic light-emitting display devices to overcome all the above-described shortcomings and problems.

For example, the display panel according to the present disclosure includes structural features that enhance reliability and manufacturing yield by preventing the formation of pores between the pixel driver and the planarization layer. An insulating layer is placed between the pixel driver and the planarization layer to reduce the chance of pores or cracks caused by thermal stress or poor adhesion. This insulating layer has lower, side, and upper portions. Openings in the upper insulating layer and the protective layer allow electrical connections to the pixel driver pads. A portion of the planarization layer also acts as a cover to help keep the pixel driver in place and prevent separation or interference during processing.

The design uses multiple layers of conductive lines formed across stacked insulating layers to route signals and power while keeping the surface even. Alignment markers and layered buffer materials improve accuracy when transferring components onto the base substrate. Each subpixel can include more than one light-emitting element of the same color, allowing the panel to adjust brightness and maintain performance even if one element fails. This helps reduce defects and supports stable image quality.

It should be noted that technical benefits of the present disclosure are not limited to the above-described benefits, and other benefits of the present disclosure will be apparent to those skilled in the art from the following descriptions.

According to an aspect of the present disclosure, there is provided a display panel including a display area including a light-emitting area in which a light-emitting element is disposed, a plurality of lines, and a plurality of pads connected to the plurality of lines, a pixel driver disposed in the display area, and an insulating layer covering the pixel driver, wherein the insulating layer includes one or more openings.

### BRIEF DESCRIPTION OF THE SEVERAL VIEWS OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a diagram illustrating a display device (in other words, a display panel thereof) according to one embodiment of the present disclosure;

FIG. 2 is an enlarged view illustrating an area A of FIG. 1;

FIG. 3 is a diagram illustrating some areas of a pixel;

FIG. 4 is a cross-sectional view along line I-I′ of FIG. 3;

FIG. 5 is a cross-sectional view along line II-II′ of FIG. 3;

FIG. 6 is a cross-sectional view along line III-III′ of FIG. 3;

FIG. 7 is a cross-sectional view illustrating an example in which a main light-emitting element and a sub light-emitting element are electrically connected to a pixel driving circuit;

FIG. 8 is a cross-sectional view of a display panel schematically illustrating one example of multilayer line patterns;

FIG. 9 is a cross-sectional view of a display panel schematically illustrating an example of a pixel driver structure that is applicable to one embodiment of the present disclosure;

FIG. 10 is a plan view of a pixel driver after a transfer process;

FIG. 11 is an enlarged view illustrating a section B of FIG. 10;

FIG. 12 is a cross-sectional view along line IV-IV′ of FIG. 10; and

FIG. 13 is a cross-sectional view along line V-V′ of FIG. 11.

### DETAILED DESCRIPTION

Advantages and features of the present disclosure and methods for achieving them will be made clear from embodiments described in detail below with reference to the accompanying drawings. The present disclosure may be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to substantially the same components throughout the present specification. Further, in the following description of the present disclosure, when detailed description of a known related art is determined to unnecessarily obscure the gist of the present disclosure, the detailed description thereof will be omitted herein.

When the terms “provided with”, “including”, “having”, “consisting of”, and the like mentioned in the present disclosure are used, other parts may be added unless the term “only” is used. When a component is expressed as a singular number, the singular number can be construed as a plural number unless otherwise specified.

In analyzing a component, it is interpreted as including an error range even when there is no explicit description.

When the positional relationship and interconnection between two components are described, such as “on”, “above”, “below”, “next to”, “connected or coupled”, “crossing or intersecting”, etc., one or more other components may be interposed between these components, unless there is mention of “immediately” or “directly.”

To further elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

When a temporal predecessor relationship is described as being “after”, “subsequent”, “next to”, “prior to”, or the like, unless “immediately” or “directly” is used, cases may not be continuous on the time axis.

In order to distinguish components, “first”, “second”, etc., may be used before the name of the component, but this ordinal number or component name does not limit its function or structure. For convenience of description, ordinal numbers preceding the names of identical components may be different between embodiments.

The following embodiments can be partially or fully coupled to or combined with each other, and various technological interconnections and drives are possible. The embodiments may each be implemented independently from each other or may be implemented together in association.

Hereinafter, various embodiments of the present disclosure will be described in detail with reference to the accompanying drawings.

A display device according to one embodiment of the present disclosure includes a display panel having a display area or screen in which an image is displayed, and a pixel driver for driving pixels of the display panel. The display area includes a pixel area in which the pixels are disposed. The pixel area includes a plurality of light-emitting areas. A light-emitting element is disposed in each of the light-emitting areas. The pixel driver may be embedded in the display panel.

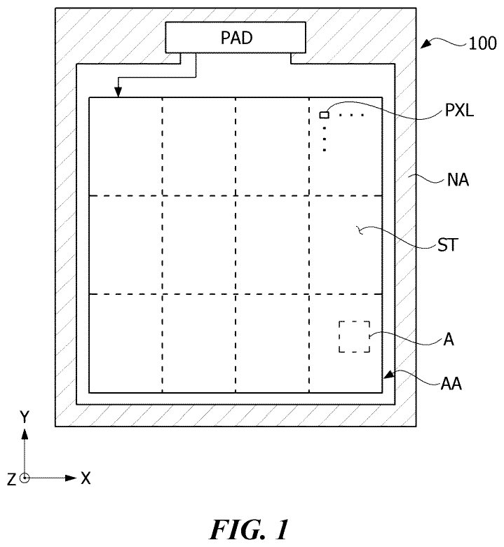

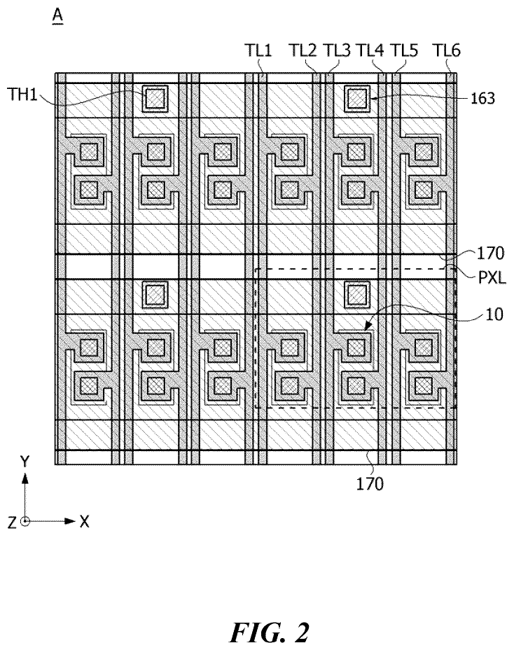

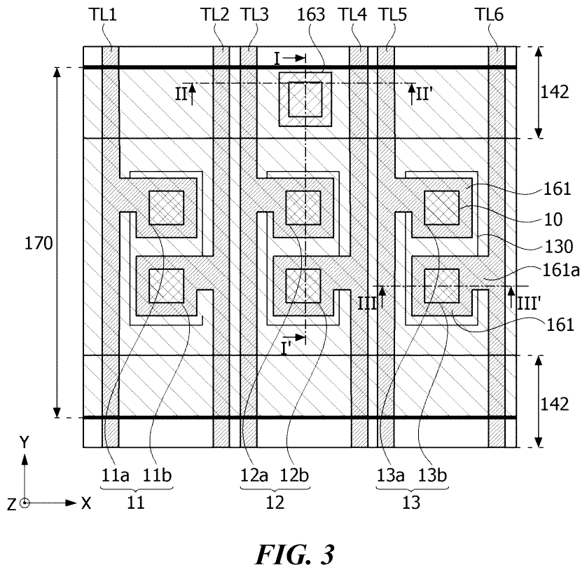

FIG. 1 is a diagram illustrating a display device (in other words, a display panel thereof) according to one embodiment of the present disclosure. FIG. 2 is an enlarged view illustrating an area A of FIG. 1. FIG. 3 is a diagram illustrating some areas of a pixel.

Referring to FIGS. 1 and 2, a display device 100 according to one embodiment of the present disclosure includes a display panel on which an input image is visually reproduced. The display panel may include a display area AA in which an image is displayed and a non-display area NA in which an image is not displayed. In the non-display area NA, various lines and driving circuits may be disposed (or mounted), and a pad portion PAD to which integrated circuits and printed circuits are connected may be disposed.

A plurality of light-emitting elements 10 disposed in the display area AA to form a pixel PXL may be micro-sized inorganic light-emitting elements. The inorganic light-emitting element may be grown on a silicon wafer and then attached to the display panel through a transfer process.

The transfer process of the light-emitting element 10 may be performed for each pre-partitioned area. In FIG. 1, the display area AA is divided into 12 transfer areas ST, but the sizes of the transfer areas or the number of divisions is not limited thereto. The transfer process may be performed sequentially or simultaneously in a first transfer area ST to a twelfth transfer area ST. In the transfer areas ST, a blue light-emitting element 10, a green light-emitting element 10, and a red light-emitting element 10 may be sequentially transferred.

In the non-display area NA, a data driving circuit or a gate driving circuit may be disposed, and lines that supply control signals for controlling the driving circuits may be disposed. Here, the control signals include various timing signals including a clock signal, an input data enable signal, and a synchronization signal and may be received through the pad portion PAD.

The pixels PXL may be driven by pixel drivers. The pixel drivers may receive a driving voltage, an image signal (digital signal), and a synchronization signal synchronized with the image signal and output an anode voltage and a cathode voltage of the light-emitting element 10 to drive a plurality of pixels. The driving voltage may be a high potential voltage EVDD. The cathode voltage may be a low potential voltage EVSS commonly applied to the pixels. The anode voltage may be a voltage corresponding to a pixel data value of the image signal. The pixel driver may be disposed in the non-display area NA or in a lower part of the display area AA.

Each pixel PXL may include a plurality of sub-pixels having different colors. For example, the plurality of pixels may each include a red sub-pixel in which a light-emitting element 10 emitting light of a red wavelength is disposed, a green sub-pixel in which a light-emitting element 10 emitting light of a green wavelength is disposed, and a blue sub-pixel in which a light-emitting element 10 emitting light of a blue wavelength is disposed. The plurality of pixels may further include white pixels.

Referring to FIGS. 2 and 3, the plurality of pixels PXL may be consecutively disposed in a first direction (X-axis direction) and a second direction (Y-axis direction). A plurality of sub-pixels having the same color may be disposed in the pixel in the display area AA. For example, each of the plurality of pixels may include a first red sub-pixel in which a 1-1 light-emitting element 11a emitting light of a red wavelength is disposed, a second red sub-pixel in which a 1-2 light-emitting element 11b emitting light of a red wavelength is disposed, a first green sub-pixel in which a 2-1 light-emitting element 12a emitting light of a green wavelength is disposed, a second green sub-pixel in which a 2-2 light-emitting element 12b emitting light of a green wavelength is disposed, a first blue sub-pixel in which a 3-1 light-emitting element 13a emitting light of a blue wavelength is disposed, and a second blue sub-pixel in which a 3-2 light-emitting element 13b emitting light of a blue wavelength is disposed. The 1-1 light-emitting element 11a, the 2-1 light-emitting element 12a, and the 3-1 light-emitting element 13a may be construed as the main light-emitting elements. The 1-2 light-emitting element 11b, the 2-2 light-emitting element 12b, and the 3-2 light-emitting element 13b may be construed as the sub light-emitting elements.

Each sub-pixel may include two or more light-emitting elements, and thus when one light-emitting element fails, brightness of the sub-pixel may be adjusted by increasing brightness of other light-emitting element(s). However, the present disclosure is not necessarily limited thereto, and one sub-pixel may include only one light-emitting element.

A plurality of first electrodes 161 are each disposed below one of the light-emitting elements 10 and may be selectively connected to a plurality of signal lines, for example, first to sixth signal lines TL1 to TL6 by extensions 161a. The high potential voltage may be applied to the pixel drivers through the first to sixth signal lines TL1 to TL6. The first to sixth signal lines TL1 to TL6 and the first electrodes 161 may be formed as an integrated electrode pattern during an electrode pattern process.

For example, the first signal line TL1 may be connected to an anode electrode of the first red sub-pixel, and the second signal line TL2 may be connected to an anode electrode of the second red sub-pixel. The third signal line TL3 may be connected to an anode electrode of the first green sub-pixel, and the fourth signal line TL4 may be connected to an anode electrode of the second green sub-pixel. The fifth signal line TL5 may be connected to an anode electrode of the first blue sub-pixel, and the sixth signal line TL6 may be connected to an anode electrode of the second blue sub-pixel. When one sub-pixel includes only one light-emitting element, the number of signal lines TL may be reduced by half.

The second electrode 170 may be a cathode electrode that is disposed in each row and applies a cathode voltage to the light-emitting elements 10 consecutively disposed in the first direction (X-axis direction). The plurality of second electrodes 170 may be disposed to be spaced apart from each other in the second direction (Y-axis direction). The plurality of second electrodes 170 may be electrically connected to contact electrodes 163 through contact holes TH1 disposed in the contact electrodes 163. The plurality of second electrodes 170 may be connected to a cathode voltage source through the contact electrodes 163. However, the present disclosure is not particularly limited thereto, and the second electrode 170 may be formed of one electrode layer rather than being divided into a plurality of pieces and may serve as a common electrode.

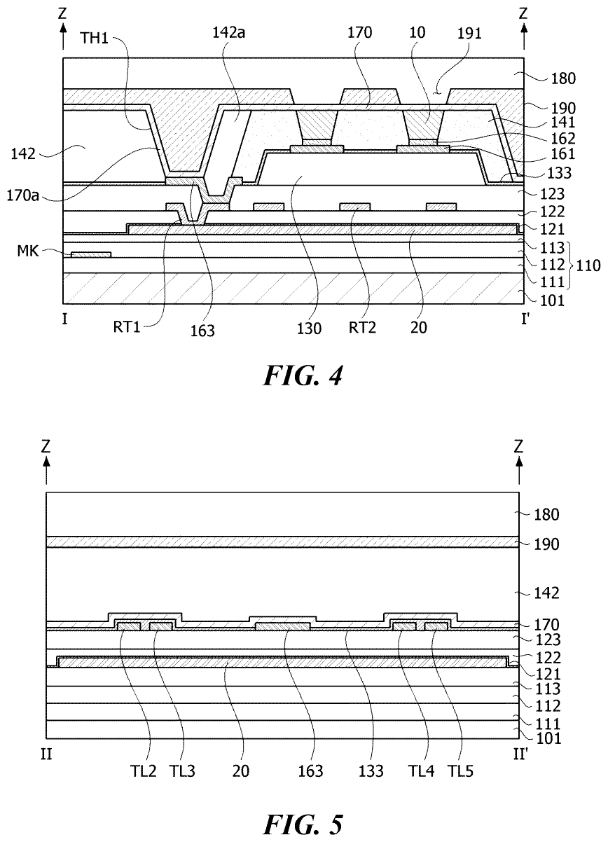

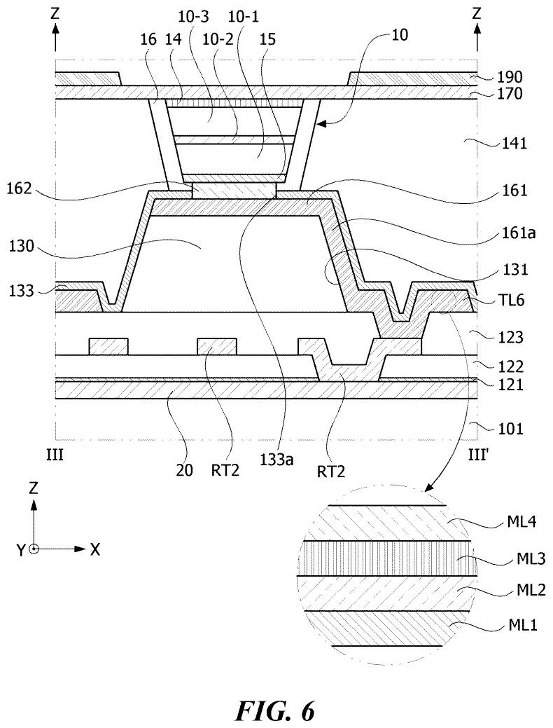

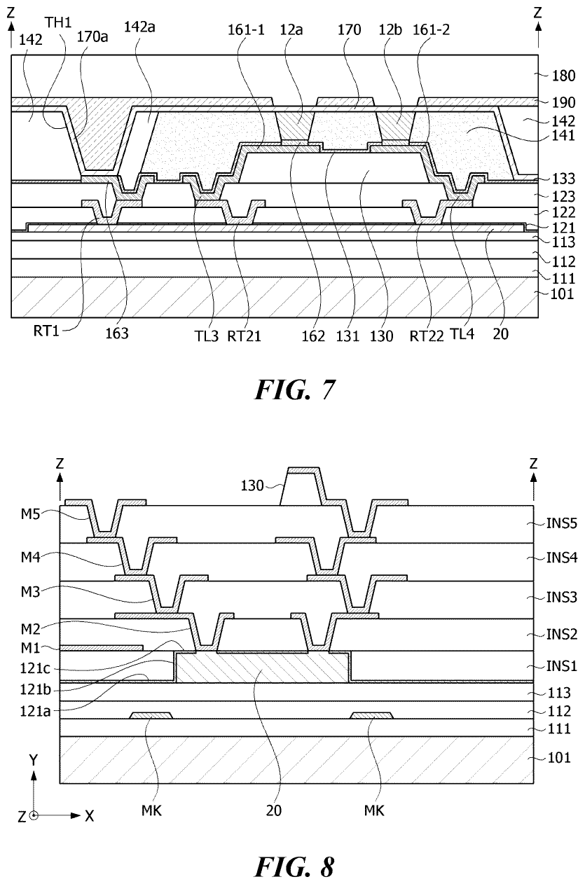

FIG. 4 is a cross-sectional view along line I-I′ of FIG. 3. FIG. 5 is a cross-sectional view along line II-II′ of FIG. 3. FIG. 6 is a cross-sectional view along line III-III′ of FIG. 3. FIG. 7 is a cross-sectional view illustrating an example in which two light-emitting elements are connected to the pixel driver.

Referring to FIGS. 4 and 5, the display device (in other words, the display panel thereof) according to the embodiment includes a plurality of first electrodes 161 and contact electrodes 163 disposed on a substrate 101, the plurality of light-emitting elements 10 disposed on the plurality of first electrodes 161, a first optical layer 141 disposed between the plurality of light-emitting elements 10, and a second electrode 170 disposed on the plurality of light-emitting elements 10.

The substrate 101 may be made of a plastic having flexibility. For example, the substrate 101 may be manufactured as a single-layer or multi-layer substrate made of a material selected from polyimide, polyethylene terephthalate, polyethylene naphthalate, polycarbonate, polyethersulfone, polyarylate, polysulfone, and a cyclic-olefin copolymer, but the present disclosure is not limited thereto. For example, the substrate 101 may be a ceramic substrate or a glass substrate.

A plurality of buffer layers may be disposed on the substrate 101. The plurality of buffer layers may be used by stacking multiple layers of inorganic insulating materials, such as silicon nitride (SiNₓ) or silicon oxide (SiO₂) or by stacking multiple layers of organic insulating materials and inorganic insulating materials.

The plurality of buffer layers may include first and second buffer layers 111 and 112. The first and second buffer layers 111 and 112 may be disposed in a multi-layered form in which the second buffer layer 112 is disposed on the first buffer layer 111. An align key MK for alignment of the pixel driver 20 and the light-emitting element 10 during the transfer process may be disposed on the first buffer layer 111. The align key MK may guide an attachment location of the pixel driver 20 and light-emitting element 10 during the transfer process. The second buffer layer 112 may be disposed to cover the first buffer layer 111 and the align key MK.

An adhesive layer 113 may be disposed on the second buffer layer 112. The pixel driver 20 may be mounted on the adhesive layer 113 in the transfer process. As shown in FIG. 4, the first buffer layer 111, the second buffer layer 112 and the adhesive layer 113 may be collectively referred to as a buffer layer unit 110.

The pixel driver 20 may be disposed in the display area AA on the substrate 101. The pixel driver 20 may be a driver manufactured on a single crystal semiconductor substrate 101 using a metal-oxide-silicon field effect transistor (MOSFET) manufacturing process. The pixel driver 20 may drive the plurality of sub-pixels.

An insulating layer 121 may be disposed on the adhesive layer 113 to cover the pixel driver 20. An inorganic insulating material, such as SiNₓ or SiO₂, may be used as the insulating layer 121.

A planarization layer 122 may be disposed on the insulating layer 121. The planarization layer 122 may be made of an organic insulating material, such as photosensitive photo acryl or photosensitive polyimide, but the present disclosure is not limited thereto. The planarization layer 122 may be made by stacking organic insulating materials and inorganic insulating materials in multiple layers.

An organic material layer 123 may be disposed on the planarization layer 122. The organic material layer 123 may be made of an organic insulating material, such as photosensitive photo acryl or photosensitive polyimide, but the present disclosure is not limited thereto.

First and second connection lines RT1 and RT2 may be disposed on the planarization layer 122. The first and second connection lines RT1 and RT2 may be connected to at least one of the first to sixth signal lines TL1 to TL6. For example, the first and second connection lines RT1 and RT2 may be connected to corresponding first to sixth signal lines TL1 to TL6. The first and second connection lines RT1 and RT2 may include a plurality of line patterns disposed on different layers with one or more insulating layers interposed therebetween. The line patterns disposed on different layers may be electrically connected through contact holes passing through the insulating layers.

A plurality of bank patterns 130 may be disposed on the organic material layer 123. At least one light-emitting element 10 may be disposed on each bank pattern 130. For example, as shown in FIG. 3, the first light-emitting element 11 including the 1-1 light-emitting element 11a and the 1-2 light-emitting element 11b may be disposed on a first bank pattern, the second light-emitting element 12 including the 2-1 light-emitting element 12a and the 2-2 light-emitting element 12b may be disposed on a second bank pattern, and the third light-emitting element 13 including the 3-1 light-emitting element 13a and the 3-2 light-emitting element 13b may be disposed on a third bank pattern.

The bank pattern 130 may be made of an organic insulating material, such as photosensitive photo acryl or photosensitive polyimide, but the present disclosure is not limited thereto. The bank pattern 130 may guide an attachment location of the light-emitting element 10 during the transfer process of the light-emitting element 10. The bank pattern 130 may be omitted.

A solder pattern 162 may be disposed on a first electrode 161. The solder pattern 162 may be made of indium (In), tin (Sn), or an alloy thereof, but the present disclosure is not limited thereto.

Each of the plurality of light-emitting elements 10 may be mounted on the solder pattern 162. One pixel may include light-emitting elements 10 of three colors. The first light-emitting element 11 may be a red light-emitting element, the second light-emitting element 12 may be a green light-emitting element, and the third light-emitting element 13 may be a blue light-emitting element. Two light-emitting elements may be mounted in each sub-pixel.

The first optical layer 141 may cover the plurality of light-emitting elements 10 and the plurality of bank patterns 130. Therefore, the first optical layer 141 may cover the spaces between the plurality of light-emitting elements 10 and between the plurality of bank patterns 130. The first optical layer 141 may extend in the first direction X and be spaced apart in the second direction Y to be separated between pixel rows.

The first optical layer 141 may include an organic insulating material in which fine metal particles, such as titanium dioxide particles, are dispersed. Light emitted from the plurality of light-emitting elements 10 may be scattered by the fine metal particles dispersed in the first optical layer 141 and emitted to the outside.

The second electrode 170 may be disposed on the plurality of light-emitting elements 10. The second electrode 170 may be commonly connected to the plurality of pixels PXL. The second electrode 170 may be a thin electrode that transmits light. The second electrode 170 may be made of a transparent electrode material, such as indium tin oxide (ITO), but the present disclosure is not necessarily limited thereto.

The second electrode 170 may extend in the first direction (X-axis direction) and be spaced apart in the second direction (Y-axis direction). The second electrode 170 may be electrically connected to the contact electrode 163 through a contact hole TH1 formed in a second optical layer 142. The second optical layer 142 may include the contact hole TH1 exposing the contact electrode 163. The second electrode 170 may be inserted into the contact hole TH1 of the second optical layer 142 and come into contact with an upper surface of the contact electrode 163. The contact hole TH1 may be formed in an outer area of the pixel.

The second optical layer 142 may be an organic insulating material surrounding the first optical layer 141. The second optical layer 142 may be disposed on the organic material layer 123 together with the first optical layer 141. The first optical layer 141 and the second optical layer 142 may include the same material (e.g., siloxane). For example, the first optical layer 141 may be a siloxane containing titanium oxide (TiOₓ), and the second optical layer 142 may be a siloxane not containing TiOₓ. However, the present disclosure is not necessarily limited thereto, and the first optical layer 141 and the second optical layer 142 may be formed of the same material or different materials.

An upper surface of the second optical layer 142 may be coplanar with an upper surface of the second electrode 170. That is, the first optical layer 141 and the second optical layer 142 may function as a planarization layer. Consequently, since there is no step on a surface where a black matrix 190 is formed, a pattern of the black matrix 190 may be easily formed on the first optical layer 141 and the second optical layer 142. However, the present disclosure is not necessarily limited thereto, and the upper surfaces of the second optical layer 142 and the second electrode 170 may have different heights.

The black matrix 190 may be an organic insulating material to which a black pigment is added. The second electrode 170 may be in contact with the contact electrode 163 below the black matrix 190. Through-holes 191 through which the light emitted from the light-emitting elements 10 is emitted to the outside may be formed between patterns of the black matrix 190. The problem of mixing of light emitted from adjacent light-emitting elements 10 with the first optical layer 141 in between may be solved by the black matrix 190.

The encapsulation layer 180 may be an organic insulating material covering the black matrix 190 and the second electrode 170. In FIG. 3, the black matrix 190 and the encapsulation layer 180 are omitted.

The contact electrode 163 may be electrically connected to the first connection line RT1 disposed thereunder, and the first connection line RT1 may be connected to the pixel driver 20. Therefore, the second electrode 170 may apply a cathode voltage through the contact electrode 163. The first electrode 161 may be electrically connected to a second connection line RT2. This will be described below.

Referring to FIG. 5, the contact electrode 163 and the first to sixth signal lines TL1 to TL6 may be disposed on the same plane. The pixel driver 20 may be disposed below the contact electrode 163 and the first to sixth signal lines TL1 to TL6. When the pixel driver 20 is composed of a plurality of pixel drivers, a plurality of pixel drivers may be disposed in the display panel.

The passivation layer 133 may expose the contact electrode 163 to electrically connect the contact electrode 163 to the second electrode 170. In addition, the passivation layer 133 may insulate the second to fifth signal lines TL2 to TL5 from the second electrode 170.

Referring to FIG. 6, the first electrode 161 may extend to one side surface 131 of the bank pattern 130 and to the top of the organic material layer 123, so as to be electrically connected to the second connection line RT2 disposed on the planarization layer 122.

The first electrode 161, a connector 161a, the signal line TL (for example, the first to sixth signal lines TL1 to TL6) and/or the first and second connection lines RT1 and RT2 may include a single-layer or multi-layer metal layer selected from titanium (Ti), molybdenum (Mo), and aluminum (Al). The first electrode 161, the connector 161a, the signal line TL and/or the first and second connection lines RT1 and RT2 may be formed into a multi-layer structure including a first layer ML1, a second layer ML2, a third layer ML3, and a fourth layer ML4.

The first layer ML1 and the third layer ML3 may each contain Ti or Mo. The second layer ML2 may contain A1. The fourth layer ML4 may include a transparent conductive oxide layer, such as ITO or indium zinc oxide (IZO), which has a good adhesion to the solder pattern 162 and has good corrosion resistance and acid resistance.

The first layer ML1, the second layer ML2, the third layer ML3, and the fourth layer ML4 may be sequentially deposited and then patterned by performing a photolithography process and an etching process.

The passivation layer 133 may include an opening hole 133a disposed on the first electrode 161 and the signal line TL to expose the solder pattern 162.

The light-emitting element 10 may include a first conductive semiconductor layer 10-1, an active layer 10-2 disposed on the first conductive semiconductor layer 10-1, and a second conductive semiconductor layer 10-3 disposed on the active layer 10-2. A first driving electrode 15 may be disposed below the first conductive semiconductor layer 10-1, and a second driving electrode 14 may be disposed on the second conductive semiconductor layer 10-3.

The light-emitting element 10 may be formed on a silicon wafer using a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering.

The first conductive semiconductor layer 10-1 may be implemented of a Group III-V or II-VI compound semiconductor and may be doped with a first dopant. The first conductive semiconductor layer 10-1 may be formed of a semiconductor material having a composition formula of Alₓ₁In_{y1}Ga_{(1-x1-yl)}N (0≤x1≤1, 0≤y1≤1, and 0≤x1+y1≤1) and one or more materials selected from among InAlGaN, AlGaAs, GaP, GaAs, GaAsP, and AlGaInP. When the first dopant is an n-type dopant such as Si, Ge, Sn, Se, or Te, the first conductive semiconductor layer 10-1 may be an n-type nitride semiconductor layer. However, when the first dopant is a p-type dopant, the first conductive semiconductor layer 10-1 may be a p-type nitride semiconductor layer.

The active layer 10-2 is a layer in which electrons (or holes) injected through the first conductive semiconductor layer 10-1 and holes (or electrons) injected through the second conductive semiconductor layer 10-3 meet. The active layer 10-2 may be transited to a low energy level due to recombination of electrons and holes to emit light having a wavelength corresponding to the transition.

The active layer 10-2 may have any one of a single well structure, a multi-well structure, a single quantum well structure, a multi quantum well (MQW) structure, a quantum dot structure, or a quantum wire structure, but the structure of the active layer 10-2 is not limited thereto. The active layer 10-2 may generate light of a visible wavelength band. For example, the active layer 10-2 may output light of any one wavelength band of blue, green, and red.

The second conductive semiconductor layer 10-3 may be disposed on the active layer 10-2. The second conductive semiconductor layer 10-3 may be formed of a Group III-V or II-VI compound semiconductor and may be doped with a second dopant. The second conductive semiconductor layer 10-3 may be formed of a semiconductor material having a composition formula of Inₓ₂Al_{y2}Ga_{1-x2-y2}N (0≤x2≤1, 0≤y2≤1, and 0x2+y2≤1) or a material selected from among AlInN, AlGaAs, GaP, GaAs, GaAsP, and AlGaInP. When the second dopant is a p-type dopant such as Mg, Zn, Ca, Sr, or Ba, the second conductive semiconductor layer 10-3 doped with the second dopant may be a p-type semiconductor layer. When the second dopant is an n-type dopant, the second conductive semiconductor layer 10-3 may be an n-type nitride semiconductor layer.

A reflective layer 16 may be disposed on side surfaces and a bottom portion of the light-emitting element 10. The reflective layer 16 may have a structure in which a reflective material is dispersed in a resin layer, but the present disclosure is not necessarily limited thereto. For example, the reflective layer 16 may be manufactured as reflectors of various structures. Light emitted from the active layer 10-2 may be reflected upward by the reflective layer 16, thereby increasing light extraction efficiency.

In the embodiment, although the vertical structure in which the second and first driving electrodes 14 and 15 are disposed on the top and bottom portions of the light-emitting element (in other words, the light-emitting structural body) has been described, the light-emitting element may have a lateral structure or a flip chip structure in addition to the vertical structure.

Referring to FIG. 7, the 2-1 light-emitting element (or main light-emitting element) 12a and the 2-2 light-emitting element (or sub light-emitting element) 12b of the sub-pixel may be disposed on the bank pattern 130. An example of the second light-emitting element 12 will be described. A 1-1 electrode 161-1 connected to the 2-1 light-emitting element (or main light-emitting element) 12a may extend to one surface of the bank pattern 130 to be electrically connected to a 2-1 connection line RT21 disposed thereunder. A 1-2 electrode 161-1 connected to the 2-2 light-emitting element (or sub light-emitting element) 12b may extend to the other surface of the bank pattern 130 to be electrically connected to a 2-2 connection line RT22 disposed thereunder.

The pixel driver 20 may apply an anode voltage to the 2-1 light-emitting element (or main light-emitting element) 12a through the 2-1 connection line RT21 and apply the anode voltage to the sub light-emitting element 12b through the 2-2 connection line RT22. The pixel driver 20 may apply a cathode voltage to the 2-1 light-emitting element (or main light-emitting element) 12a and the 2-2 light-emitting element (or sub light-emitting element) 12b through the first connection line RT1 and the second electrode 170.

The pixel driver 20 may control a brightness of the sub-pixel by driving only the 2-1 light-emitting element (or main light-emitting element 12a) or by simultaneously driving the 2-1 light-emitting element (or main light-emitting element) 12a and the 2-2 light-emitting element (or sub light-emitting element) 12b. When the 2-1 light-emitting element (or main light-emitting element) 12a is darkened, the brightness may be controlled by driving only the 2-2 light-emitting element (or sub light-emitting element) 12b.

FIG. 8 is a cross-sectional view of a display panel schematically illustrating an example of multi-layer line patterns that is applicable to one embodiment of the present disclosure.

Referring to FIG. 8, a single layer or a plurality of insulating layers may be stacked on the substrate 101. For example, the plurality of insulating layers may include first to fifth insulating layers INS1 to INS5. Each of the first to fifth insulating layers INS1 to INS5 may be formed as a single layer or a plurality of insulating layers.

One or more pixel drivers 20 may be disposed on the substrate 101. At least a portion of each of the pixel drivers 20 may be buried by the first insulating layer INS1. A first line pattern M1 may be disposed on the first insulating layer INS1. The second insulating layer INS2 includes openings exposing output terminals of the pixel driver 20 and/or the first line pattern M1. A second line pattern M2 may be disposed on the second insulating layer INS2. A portion of the second line pattern M2 may be in contact with the output terminal of the pixel driver 20 and/or the first line pattern M1 through contact holes passing through the organic material layer INS2. The third insulating layer INS3 may include contact holes exposing a portion of the second line pattern M2. A third line pattern M3 may be disposed on the third insulating layer INS3. A portion of the third line pattern M3 may be in contact with the second line pattern M2 through contact holes passing through the third insulating layer INS3.

The fourth insulating layer INS4 may include contact holes exposing a portion of the third line pattern M3. A fourth line pattern M4 may be disposed on the fourth insulating layer INS4. A portion of the fourth line pattern M4 may be in contact with the third line pattern M3 through contact holes passing through the fourth insulating layer INS4. The fifth insulating layer INS5 may include contact holes exposing a portion of the fourth line pattern M4. A fifth line pattern M5 may be disposed on the fifth insulating layer INS5. A portion of the fifth line pattern M5 may be in contact with the fourth line pattern M4 through contact holes passing through the fifth insulating layer INS5. The fifth line pattern M5 may include a metal pattern electrically connected to the first electrode of the light-emitting element and a metal pattern connected to the second electrode of the light-emitting element.

The line structure of the display panel is not limited to what is shown in FIG. 8. For example, the third line pattern M3 may be connected to the first line pattern M1 through contact holes passing through the second and third insulating layers INS2 and INS3 stacked therebelow. The first electrode and the second electrode of the light-emitting element may be electrically connected to a preset metal pattern among the first to fourth line patterns through the contact holes passing through the insulating layers.

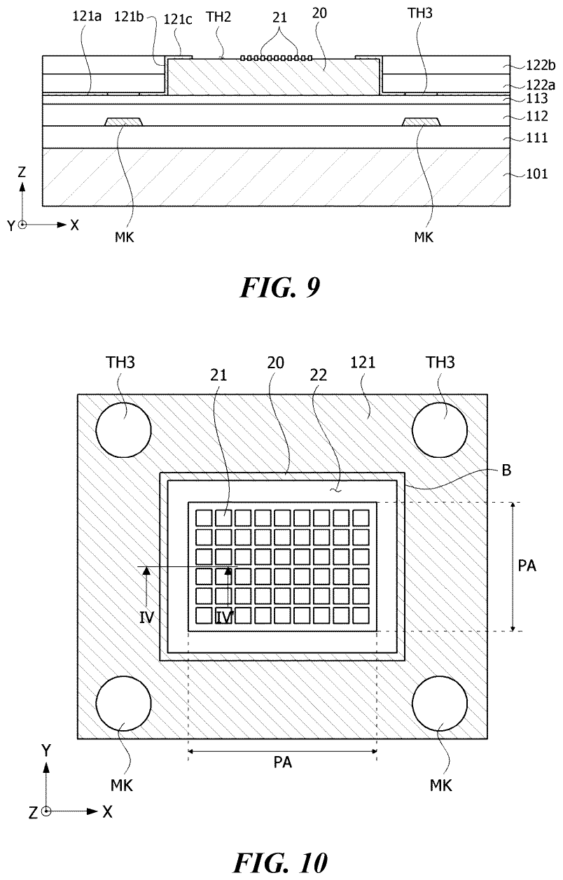

FIG. 9 is a cross-sectional view of a display panel schematically illustrating an example of a pixel driver structure that is applicable to one embodiment of the present disclosure.

Referring to FIG. 9, the first and second buffer layers 111 and 112 may be disposed on the substrate 101. The first and second buffer layers 111 and 112 may be disposed as a single first buffer layer 111 (that is, the second buffer layer 112 can be omitted) or a first buffer layer 111 and a second buffer layer 112 consisting of N multi-layers (N is an integer greater than or equal to 2) disposed on the first buffer layer 111. The adhesive layer 113 may be disposed on an N^{th} buffer layer which is disposed as an uppermost layer of the N multi-layers. The first and second buffer layers 111 and 112 may also be disposed as double-layered buffer layers consisting of one first buffer layer 111 and one second buffer layer 112. In this case, for example, the adhesive layer 113 may be disposed on the second buffer layer 112 disposed as an uppermost layer of the double-layered buffer layers.

The adhesive layer 113 may function to adhere the pixel driver 20 to the substrate after the transfer process.

The adhesive layer 113 may include an ultraviolet or thermosetting sealant. The present disclosure is not limited thereto, and any method and material with which the pixel driver 20 can be mounted may be included. The align key MK for aligning the pixel driver 20 and the light-emitting element 10 may be disposed on the first buffer layer 111. The pixel driver 20 guided using the align key MK may be mounted on the adhesive layer 113 through a transfer process.

The insulating layer 121 may be disposed on the adhesive layer 113 to cover the pixel driver 20. The insulating layer 121 may be disposed through an atomic laser deposition (ALD) process. The present disclosure is not limited thereto, and any process through which an insulating layer can be arranged may be used. For example, the insulating layer may be deposited using a chemical vapor deposition (CVD) process.

The insulating layer 121 may include a lower insulating layer 121a disposed on the adhesive layer 113, a side insulating layer 121b disposed on a side surface of the pixel driver 20, and an upper insulating layer 121c disposed on the pixel driver 20.

The lower insulating layer 121a may further include one or more openings TH3 for discharging an out gas generated from the organic material layer and/or inorganic material layer below the insulating layer 121. The opening TH3 may be disposed in an area overlapping the align key MK in a height direction (Z-axis) of the display panel.

First and second planarization layers 122a and 122b may be disposed on the lower insulating layer 121a. The first and second planarization layers 122a and 122b may be disposed as a single first planarization layer 122a (that is, the second planarization layer 122b can be omitted) or a first planarization layers 122a and a second planarization layer 122b consisting of N multi-layers (N is an integer greater than or equal to 2) disposed on the first planarization layer 122a. The first and second planarization layers 122a and 122b may also be disposed as double-layered planarization layers consisting of one first planarization layers 122a and one second planarization layer 122b. In the example as shown in FIG. 9 of the present disclosure, the planarization layer 122 is disposed as two multi-layers consisting of one first planarization layers 122a and one second planarization layer 122b.

Some of (in other words, at least a portion of) a plurality of pads 21, to which line patterns M0 are electrically connected, may be disposed on the pixel driver 20 and embedded (in particular, partly embedded) in the pixel driver 20.

The upper insulating layer 121c may include one or more openings TH2. The pads 21 of the pixel driver may be exposed through the openings TH2 to be electrically connected to the line patterns M0.

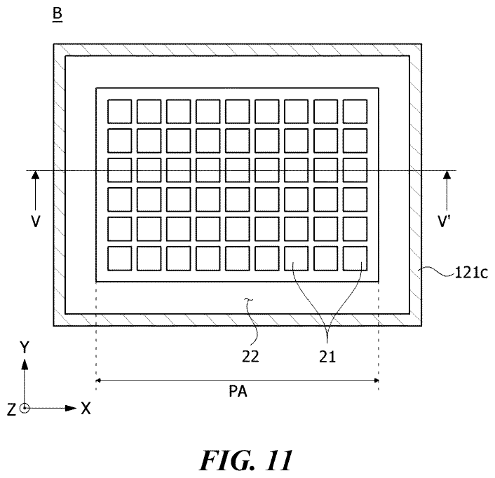

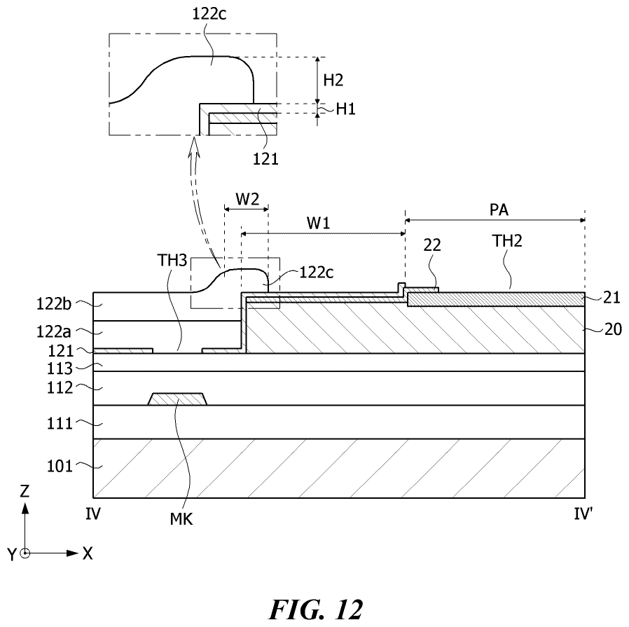

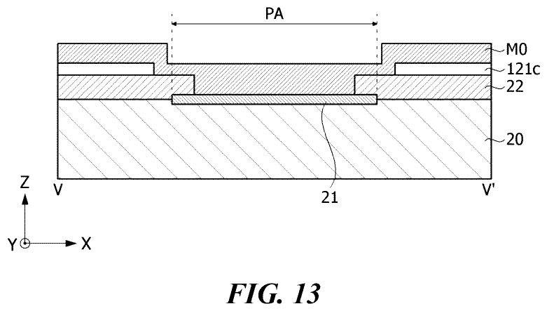

FIG. 10 is a plan view of the pixel driver after the transfer process. FIG. 11 is an enlarged view illustrating a section B of FIG. 10. FIG. 12 is a cross-sectional view along line IV-IV′ of FIG. 10.

FIG. 13 is a cross-sectional view along line V-V′ of FIG. 11.

Referring to FIGS. 10 to 13, one or more align keys MK may be disposed adjacent to corners of the pixel driver 20.

An upper portion of the pixel driver 20 in which the pads 21 are disposed may be defined as a pad area PA.

A portion of the second planarization layer 122b may be disposed as a cover layer 122c covering a part of the upper portion of the pixel driver 20. The cover layer 122c is disposed to cover an edge of the upper portion of the pixel driver 20 so that the pixel driver 20 may be prevented from being separated from a location to which the pixel driver 20 is initially transferred during the manufacturing process or an operation of the display device (or the display panel thereof).

When the insulating layer 121 is not disposed and the planarization layer 122 is in direct contact with the pixel driver 20, there is a problem that cracks and pores are generated in the cover layer 122c during post-processing due to low adhesion between the planarization layer 122 and the pixel driver 20. Since the insulating layer 121, which is made of a material with high adhesion to the planarization layer 122, is disposed between the planarization layer 122 and the pixel driver 20, it is possible to prevent pores from being generated during the post-processing.

A thickness H2 of the cover layer 122c and a thickness H1 of the insulating layer 121 below the cover layer 122c may be at a ratio of 100:1 or 120:1. For example, the thickness H2 of the cover layer 122c may be disposed as 0.5 μm, and the thickness H1 of the insulating layer 121 may be disposed as 50 Å.

The thickness H2 of the cover layer 122c may be disposed as a thickness between 0.3 μm and 0.7 μm. When the thickness of cover layer 122c is thicker than 0.7 μm, overtransfer may occur during the transfer of the light-emitting element 10 in the post-processing. When the thickness of cover layer 122c is less than 0.3 μm, a pore may be generated between the cover layer 122c and the pixel driver 20.

A width W2 of the cover layer 122c disposed on the insulating layer 121 and a width W1 of the upper insulating layer 121c may be at a ratio of 1:50. For example, when the width W2 of the cover layer 122c is 6 μm, the width W1 of the upper insulating layer 121c may be 300 μm.

The width W2 of the cover layer 122c may be a width between 4 μm and 8 μm. When the width W2 of the cover layer 122c is less than 4 μm, a pore may be generated between the cover layer 122c and the insulating layer 121c. When the width W2 of the cover layer 122c is more than 8 μm, overtransfer may occur in the transfer of light-emitting element 10 during the post-processing.

The pads 21 for electrical connection with connection lines M0 may be disposed on the pixel driver 20. A protective layer 22 may be disposed on an outer periphery of the pixel driver 20. The upper insulating layer 121c may be disposed on the protective layer 22.

The protective layer 22 may contain aluminum oxide (AiOₓ). The protective layer 22 may include openings at upper portions of the pads 21 (in other words, on top of the pads 21). The openings of the protective layer 22 and the opening of the upper insulating layer 121c may be disposed to overlap in the pad area PA.

The width (or opening range) of the opening of the upper insulating layer 121c may be greater than the width (or opening range) of the opening of the protective layer 22.

The connection lines M0 may be electrically connected to the plurality of pads 21 through the openings disposed in the pad area PA.

The display device and the display panel thereof according to the embodiments of the present disclosure will now be described.

The display panel according to one embodiment of the present disclosure includes a display area including a light-emitting area in which a light-emitting element is disposed, and a plurality of lines; a pixel driver disposed in the display area and including a plurality of pads connected to the lines; and an insulating layer covering the pixel driver, wherein the insulating layer includes a side insulating layer disposed on a side surface of the pixel driver and an upper insulating layer disposed on the pixel driver, the upper insulating layer includes one or more openings exposing the plurality of pads of the pixel driver, and the plurality of lines may be electrically connected to the pixel driver through the one or more openings.

According to one or more embodiments of the present disclosure, the light-emitting area may include a substrate, a buffer layer disposed on the substrate, and a planarization layer disposed on the buffer layer, and the pixel driver may be disposed under and buried by the planarization layer (in other words, disposed under and embedded in the planarization layer).

According to one or more embodiments of the present disclosure, the insulating layer may further include a lower insulating layer disposed below the planarization layer, and the lower insulating layer may include one or more openings exposing the pads of the pixel driver.

According to one or more embodiments of the present disclosure, the display panel may include a protective layer disposed on the pixel driver, and the upper insulating layer may be disposed on the protective layer.

According to one or more embodiments of the present disclosure, the protective layer may include one or more openings, and the one or more openings of the protective layer may be disposed to overlap the one or more openings of the upper insulating layer in a height direction of the display panel.

According to one or more embodiments of the present disclosure, a width (or opening range) of the one or more openings of the upper insulating layer and a width (or opening range) of the one or more openings of the protective layer may be different from each other.

According to one or more embodiments of the present disclosure, the width of the one or more openings of the upper insulating layer may be wider than the width of the one or more openings of the protective layer.

According to one or more embodiments of the present disclosure, a thickness of the upper insulating layer and a thickness of the protective layer may be different from each other.

According to one or more embodiments of the present disclosure, the thickness of the upper insulating layer may be smaller than the thickness of the protective layer.

According to one or more embodiments of the present disclosure, the planarization layer may be disposed as a single first planarization layer or a first planarization layer and a second planarization layer consisting of N multi-layers (N is an integer greater than or equal to 2) disposed on the first planarization layer, and a portion of an N^{th} planarization layer disposed as an uppermost layer among the N multi-layers may be disposed as a cover layer covering a part of an upper portion of the pixel driver.

According to one or more embodiments of the present disclosure, the cover layer may cover an upper edge of the pixel driver on which the plurality of pads of the pixel driver are not disposed.

According to one or more embodiments of the present disclosure, the cover layer may be disposed on the upper insulating layer, and a width of the upper insulating layer may be different from a width of the cover layer.

According to one or more embodiments of the present disclosure, the width of the upper insulating layer may be greater than the width of the cover layer.

According to one or more embodiments of the present disclosure, a thickness ratio of the upper insulating layer to the cover layer may be 1:100 or 1:120 in the height direction of the display panel and a width ratio thereof may be 50:1.

According to one or more embodiments of the present disclosure, a thickness ratio of the upper insulating layer to the protective layer may be 1:4.

According to one or more embodiments of the present disclosure, the buffer layer may be disposed as a single first buffer layer or a first buffer layer and a second buffer layer consisting of N multi-layers (N is an integer greater than or equal to 2) disposed on the first buffer layer, and an adhesive layer may be disposed on an N^{th} buffer layer which is disposed as an uppermost layer among the N multi-layers.

According to one or more embodiments of the present disclosure, a plurality of align keys for alignment of the pixel driver and the light-emitting element during a transfer process of the light-emitting element may be disposed on the first buffer layer.

According to one or more embodiments of the present disclosure, the plurality of align keys may each be disposed adjacent to corner areas of the pixel driver.

According to one or more embodiments of the present disclosure, the lower insulating layer may further include one or more openings disposed in an area overlapping the plurality of align keys in the height direction of the display panel.

According to one or more embodiments of the present disclosure, the insulating layer may further include SiNₓ, SiOₓ, and Si₃N₄.

The display device according to the embodiments of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical device, a desktop personal computer (PC), a laptop PC, a netbook computer, a workstation, navigation, a vehicle display device, a theater display device, a television, a wallpaper device, a signage device, a game device, a notebook, a monitor, a camera, a camcorder, and home appliances. In addition, the display device according to one or more embodiments of the present disclosure may be applied to an organic light-emitting lighting device or an inorganic light-emitting lighting device.

According to the present disclosure, an insulating layer is disposed between a pixel driver and a planarization layer, which are disposed in a display area, and thus display panel defects caused by the generation of a pore between the pixel driver and the planarization layer can be prevented using the insulating layer.

According to the present disclosure, a yield of a display panel can be increased, the manufacturing process of a display panel can be optimized, and production energy can be reduced.

It should be noted that effects of the present disclosure are not limited to the above-described effects, and other effects of the present disclosure will be apparent to those skilled in the art from the appended claims.

Since the content of the specification described in the problem to be solved, the problem solving means, and the effect to be solved does not specify the essential characteristics of the appended claims, the scope of the appended claims is not limited by the matters described in the content of the specification.

Although embodiments have been described in more detail with reference to the accompanying drawings, the present disclosure is not necessarily limited to these embodiments and may be variously modified without departing from the technical spirit of the present disclosure. The embodiments disclosed herein, therefore, are not to be taken in a sense for limiting the technical concept of the present disclosure but for explanation thereof, and the range of the technical concept of the present disclosure is not limited to these embodiments. Therefore, it should be understood that the above-described embodiments are not restrictive but illustrative in all aspects.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a display area including a light-emitting area in which a light-emitting element is disposed, and a plurality of lines;
a pixel driver disposed in the display area and including a plurality of pads connected to the plurality of lines; and
an insulating layer covering the pixel driver,
wherein the insulating layer includes a side insulating layer on a side surface of the pixel driver and an upper insulating layer on the pixel driver, and
wherein the upper insulating layer includes one or more openings exposing the plurality of pads of the pixel driver, and the plurality of lines are electrically connected to the pixel driver through the one or more openings.

2. The display device of claim 1, wherein the light-emitting area includes:
a substrate;
a buffer layer on the substrate; and
a planarization layer on the buffer layer,
wherein the pixel driver is disposed under and covered by the planarization layer.

3. The display device of claim 2, wherein:
the insulating layer further includes a lower insulating layer disposed below the planarization layer; and
the lower insulating layer includes one or more openings exposing the pads of the pixel driver.

4. The display device of claim 3, further comprising:
a protective layer on the pixel driver; and
wherein the upper insulating layer is on the protective layer.

5. The display device of claim 4, wherein:
the protective layer includes one or more openings; and
the one or more openings of the protective layer overlap the one or more openings of the upper insulating layer in a height direction of the display device.

6. The display device of claim 5, wherein a width of the one or more openings of the upper insulating layer and a width of the one or more openings of the protective layer are different from each other.

7. The display device of claim 6, wherein the width of the one or more openings of the upper insulating layer is wider than the width of the one or more openings of the protective layer.

8. The display device of claim 5, wherein a thickness of the upper insulating layer and a thickness of the protective layer are different from each other.

9. The display device of claim 5, wherein a thickness of the upper insulating layer is smaller than a thickness of the protective layer.

10. The display device of claim 2, wherein:
the planarization layer is disposed as a single first planarization layer or a first planarization layer and a second planarization layer consisting of N multi-layers on the first planarization layer, wherein N is an integer greater than or equal to 2; and
a portion of an N^{th} planarization layer which is disposed as an uppermost layer among the N multi-layers, is disposed as a cover layer covering a part of an upper portion of the pixel driver.

11. The display device of claim 10, wherein the cover layer covers an upper edge of the pixel driver on which the plurality of pads of the pixel driver are not disposed.

12. The display device of claim 11, wherein:
the cover layer is on the upper insulating layer; and
a width of the upper insulating layer is different from a width of the cover layer.

13. The display device of claim 12, wherein the width of the upper insulating layer is greater than the width of the cover layer.

14. The display device of claim 13, wherein a thickness ratio of the upper insulating layer to the cover layer is 1:100 or 1:120 in a height direction of the display device and a width ratio thereof is 50:1.

15. The display device of claim 6, wherein a thickness ratio of the upper insulating layer to the protective layer is 1:4.

16. The display device of claim 3, wherein:
the buffer layer is disposed as a single first buffer layer or a first buffer layer and a second buffer layer consisting of N multi-layers on the first buffer layer, wherein N is an integer greater than or equal to 2; and
the buffer layer further includes an adhesive layer disposed on an N^{th} buffer layer which is disposed as an uppermost layer among the N multi-layers.

17. The display device of claim 16, wherein a plurality of align keys for alignment of the pixel driver and the light-emitting element during a transfer process of the light-emitting element are on the first buffer layer.

18. The display device of claim 17, wherein each of the plurality of align keys is disposed adjacent to corner areas of the pixel driver.

19. The display device of claim 18, wherein the lower insulating layer further includes one or more openings disposed in an area overlapping the plurality of align keys in a height direction of the display panel.

20. The display device of claim 1, wherein the insulating layer includes at least one of SiNₓ, SiOₓ, and Si₃N₄.
